(19) United States
(12) Patent Application Publication
(10) Pub. No.: US 2007/0259190 A1
(43) Pub. Date: Nov. 8, 2007

(54) ITO transparent substrate with high resistance at low-temperature sputtering process and method for producing the same

(76) Inventors: Jau-Jier Chu, Hsin-Chu (TW); Chien-Min Weng, Hsin-Chu (TW); Shih-Liang Chou, Hsin-Chu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/415,214

(22) Filed: May 2, 2006

(51) Int. Cl. C23C 14/32; B32B 17/06; B32B 19/00

(52) U.S. Cl. 428/432; 204/192.17; 428/701; 428/702

(57) ABSTRACT

A method for producing an ITO transparent substrate with a high resistance at a low-temperature sputtering process is provided for mass production. The method is characterized by: a film of ITO mixed with metallic-oxide target and coated with multiple layers provides a transparent capacity. The film can be produced via a production line and further heated and annealed for stabilizing the high resistance thereof.

### BACKGROUND OF THE INVENTION

1. Field of the Invention

The present invention relates to an ITO transparent substrate with a high resistance at a low-temperature sputtering process and a method for producing the same, and particularly relates to a layer of metal oxide doped ITO, and mated with multiple depositing layers that overlap each other.

2. Description of the Related Art

In the optoelectronical raw material industry, ITO (layer) with high resistance is an important raw material and the process of producing the ITO layer is a key component of producing a panel. As the raw material industry is becoming more and more important, the requirements of high yield, precise control, low cost, and fast fabrication method for the row material production are increasing in importance also. The high-resistance ITO layer can be applied to touchpanel techniques, such as capacitive touchpanels and resistive touchpanels.

As is commonly known, the ITO layer plays a major role in touchpanels. For example, in resistive touchpanels, an ITO layer with high resistance replaces conductive glass or plastics with low resistance. In regard to capacitive touchpanels, an ITO layer with high resistance is necessary thereto. Therefore, the ITO layer with high light transmittance and high resistance are preferable to the touchpanel applications.

As showed in FIGS. 1A and 1C, a transmission layer 22a of a resistive touchpanel is illustrated. When the transmission layer 22a is produced via the sputtering process by the pure ITO target to form the high resistance, poor stability product is obtained. For a high classic and high definition product, the characteristic resistance and the stability of ITO film are both required to be high. For example, when a touch panel 13a contacts the resistive screen 12a, a pressure is forced near a spacer 26a. The transmission layer 22a of a contact layer 34a disposed over a glass layer 20a forces the glass layer 20a thereby, so that a location signal of a panel 24a is transmitted via a connection device 32a of a separation layer 30a. That means the conventional process stability is bad and specific resistances of the resistive touchpanel produced thereby are not easily achieved.

Reference is made to FIGS. 1B and 1D, in which a capacitive touchpanel is illustrated. The capacitive touch panel is coated with transparent electrodes that store electrical charges. When a panel 14a is touched by a finger 21a, a small amount of charge is drawn to the point of contact. Circuits located at each corner of the panel 14a measure the charge and send the data information to a controller.

A cross-sectional profile of the capacitive touchpanel is shown in FIG. 1D. A transmission layer 16a is coated on a glass 17a and further covered by an electrode layer 18a and a protection layer 19a sequentially. A conduction layer 15a is used to shield against electromagnetic waves. The design and the structure of the capacitive touchpanel can be complicated with high associated costs.

Therefore, an ITO transparent substrate being generally multi-layered that has a high resistance produced via a low-temperature sputtering process that can be formed quickly and reliably is greatly desired by the panel producing industry. In particular, a substrate made of polymer materials, (such as PMMA,) or glass, is needed in order to provide the desired stable characteristics.

### SUMMARY OF THE INVENTION

An ITO transparent substrate with a high resistance at a low-temperature sputtering process and a method for producing the same are provided. The substrate has a stable nature and is easily manufactured. Conventional fabrication equipment, with some alterations and improvements can be used to produce the substrate of the present invention.

The ITO transparent substrate with a high, stable resistance such as a resistive touchpanel of above 800 ohm/sq or a capacitive touchpanel of above 1500 ohm/sq at a low-temperature sputtering process is provided. The method includes steps of providing some refraction layers on a substrate base and further covered by a metallic oxide doped ITO top layer in order to be highly transparent and anti-reflective. A production line can be applied to the conventional manufacturing process, which is free of complex methods and procedures.

The method for producing an ITO transparent substrate includes: providing a transparent substrate base; sputtering the transparent substrate base with plasma, which is composed of ITO target mixed with metallic oxide target in order to produce at least one film. The ITO transparent substrate includes a transparent substrate base, and at least one film with metallic oxide doped ITO on the substrate base.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1A is a perspective view of a conventional resistive touchpanel;

FIG. 1B is a perspective view of a conventional capacitive touchpanel;

FIG. 1C is a cross-sectional profile of the conventional resistive touchpanel;

FIG. 1D is a cross-sectional profile of the conventional capacitive touchpanel;

FIG. 2 is a sketch of an ITO substrate line according to the present invention;

FIG. 3A is a perspective view of a first embodiment of the ITO substrate according to the present invention;

FIG. 3B is a perspective view of a second embodiment of the ITO substrate according to the present invention; and

FIG. 4 is a flow chart according to the present invention.

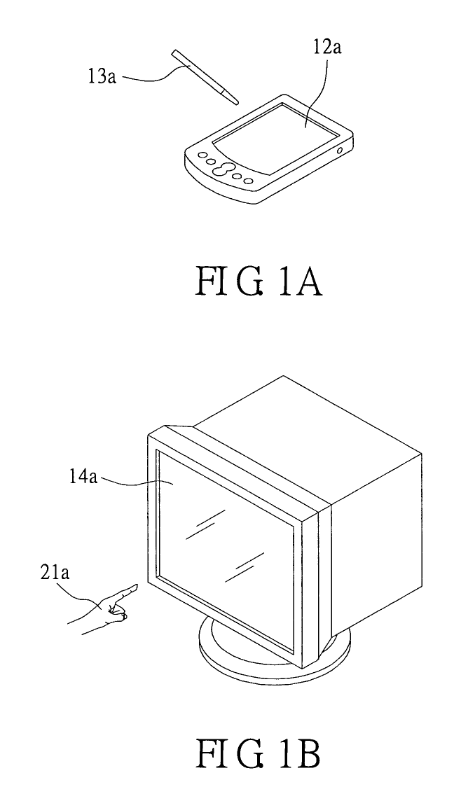

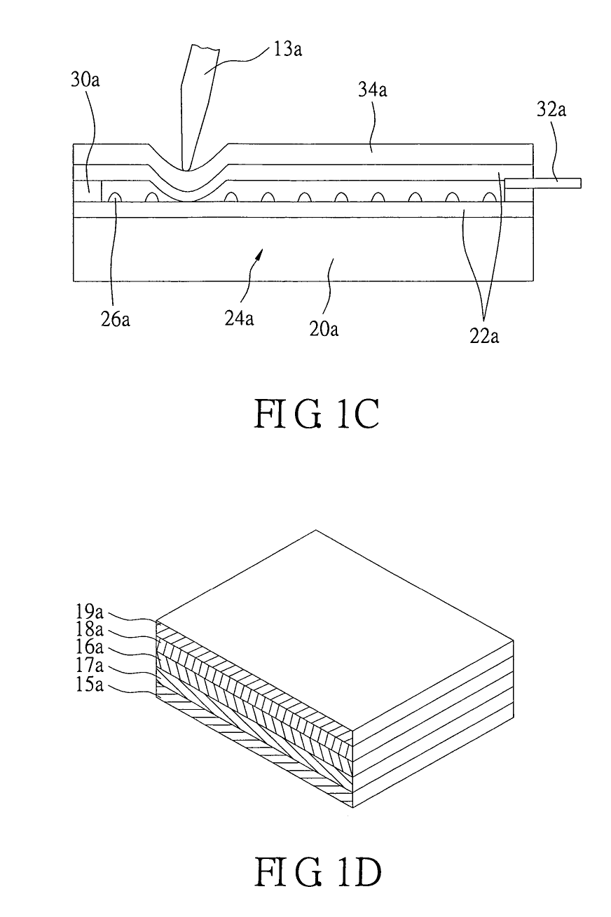

### DETAILED DESCRIPTION OF PREFERRED EMBODIMENTS

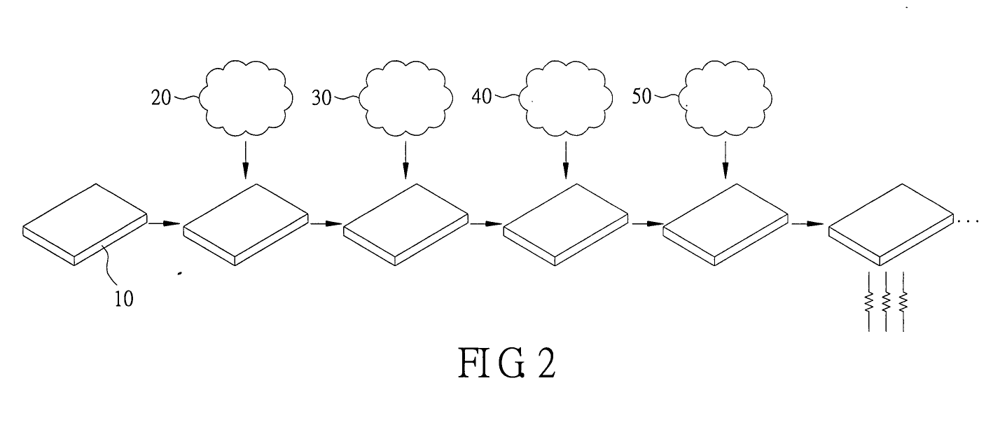

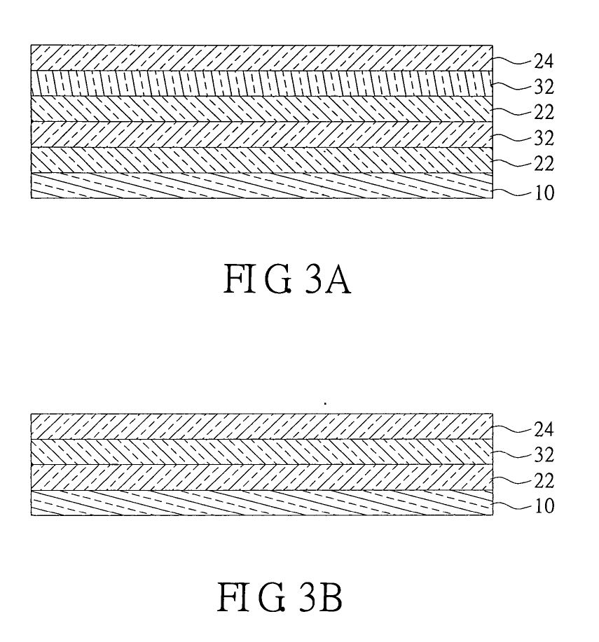

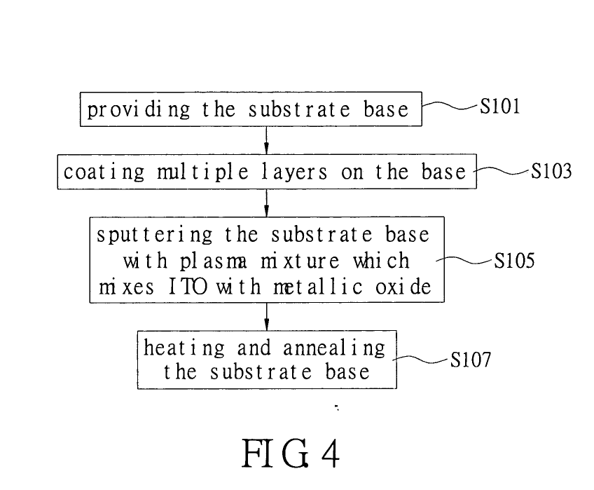

Reference is made to FIGS. 2, 3A and 3B, which show a glass treated as a substrate being adapted for a conventional simple manufacturing process for a production line. In a first embodiment, a transparent substrate base 10 is sputtered with plasma 40. Referring to FIG. 2, a sketch of the ITO substrate according to the present invention, the substrate base 10 in its initial condition is sputtered with at least one film of metallic oxide 20 or non-metallic oxide 30 (as mentioned in step S103 in FIG. 4). Furthermore, the substrate base 10 is processed with plasma 40. After the plasma 40, the substrate base 10 is processed in a predetermined auxiliary process. The substrate base 10 is heated above 300° C. (a predetermined temperature) for 30 minutes (a first predetermined period) and is further cured by an annealing process at 150˜200° C. (a predetermined range at a low temperature) for 30 minutes (a second predetermined period) in order to produce a finished product. The curing that is produced via the annealing process is described in greater detail in S107 and illustrated in FIG. 4.

In a second embodiment, the substrate base 10 is heated above 300° C. (the predetermined temperature) but the curing process is omitted to produce a stable resistance thereof. In addition, the substrate base 10 can be PMMA or other plastic materials (such as polymer materials) but with lower heated temperature.

Furthermore, at least one silicon-oxide layer is piled with the film 24, which is produced by sputtered with ITO mixed with metallic-oxide (such as Nb₂O₅) target, shown in FIGS. 3A and 3B. Naturally, a total quantity of the layers on the substrate base 10 may be 3 to 5 in order to be a multi-layered substrate. The present embodiments show the arrangement of the layers of the substrate is flexible.

FIGS. 3A and 3B illustrate a first embodiment of the layers, including a refraction layer with a high refraction index 22, a refraction layer with low refraction index 32, another refraction layer with high refraction index 22, another refraction layer with low refraction index 32, and further covered with a metallic oxide doped ITO layer 24 in FIG. 3A. A second embodiment of the layers, can include a refraction layer with high refraction index 22, a refraction layer with low refraction index 32, and a metallic oxide doped ITO layer 24 as is illustrated in FIG. 3B. The refraction layer with high refraction index 22 is made of metallic oxide 20, but the refraction layer with low refraction index 32 is made of non-metallic oxide 30.

With reference in FIG. 4, the method includes steps of: providing the substrate base 10 (step S101), coating multiple layers on the base 10 (step S103), sputtering the substrate base 10 with plasma 40 that is a mixture of ITO and metallic oxide (Nb₂O₅) (step S105), and further heating and annealing the substrate base 10.

The mixed plasma is generated by a dual gun sputtering system or a single mixed gun sputtering system. In addition, the substrate base 10 can be processed in workstations continuously connected to one another in order to guarantee a delay time controlled for a predetermined range. The transparent substrate base 10 is made of a polymer material or a glass material. Furthermore, the steps mentioned are implemented in a clean room. The transparent substrate base 10 is transited between workstations via a conveyer belt or an automatic trolley. Experimentally, these embodiments according to the present invention can provide stable resistance.

There are some advantages to the present invention:

1. The amount of Nb₂O₅ in ITO can vary the resistance thereof.

2. ITO with Nb₂O₅ can be further processed with another material to achieve high transmission.

3. The resistance thereof is more stable than that of the layer made only of ITO.

4. Not only Nb₂O₅ but also non-conductive metallic oxide material or non-metallic oxide material can be adapted thereto.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A method for producing an ITO transparent substrate with a high resistance at a low-temperature sputtering process, comprising:
providing a transparent substrate base;
sputtering plasma, which is a mixture of ITO and metallic oxide in order to produce a film on the transparent substrate base, and further being capable of implementing a predetermined auxiliary process for stabilizing the film thereof; and
providing the predetermined auxiliary process for stabilizing the film thereof in or after the step of sputtering the transparent substrate base;
wherein the transparent substrate base is heated above a predetermined temperature but without a curing process to produce a stable resistance thereof, while the step of the predetermined auxiliary process is implemented with the step of sputtering the transparent substrate base at the same time;
wherein the transparent substrate base is heated above the predetermined temperature for a first predetermined period and is further processed by an annealing process at a predetermined range of low temperature for a second predetermined period, while the step of the predetermined auxiliary process is implemented after the step of sputtering the transparent substrate base.

2. The method as claimed in claim 1, wherein the mixed plasma is generated by a dual gun sputtering system or a mixed gun sputtering system.

3. The method as claimed in claim 1, wherein the substrate base is processed in workstations continuously connected to one another in order to guarantee a delay time controlled for a predetermined range.

4. The method as claimed in claim 1, wherein the transparent substrate base is made of a polymer material or a glass material.

5. The method as claimed in claim 1, further including a step of:
sputtering a refraction layer with high or low refraction index on the substrate, before or after the step of sputtering the transparent substrate base is performed.

6. The method as claimed in claim 5, wherein the refraction layer with high refraction index is made of metallic oxide, but the refraction layer with low refraction index is made of non-metallic oxide.

7. The method as claimed in claim 6, wherein the refraction layer with high refraction index is made of Nb₂O₅, but the refraction layer with low refraction index is made of SiO₂.

8. The method as claimed in claim 1, wherein the mentioned steps are implemented in a clean room.

9. The method as claimed in claim 1, wherein the transparent substrate base is transited between workstations via a conveyer belt or an automatic trolley.

10. An ITO transparent substrate with a high resistance at a low-temperature sputtering process, comprising:
a transparent substrate base; and
at least one film mixed ITO with a metallic-oxide target, and formed on the substrate.

11. The substrate as claimed in claim 10, wherein the transparent substrate base is made of a polymer material or a glass material.

12. The substrate as claimed in claim 10, further including a refraction layer with high or low refraction index on the substrate.

13. The substrate as claimed in claim 12, wherein the refraction layer with high refraction index is made of metallic oxide, but the refraction layer with low refraction index is made of non-metallic oxide.

14. The substrate as claimed in claim 13, wherein the refraction layer with high refraction index is made of Nb₂O₅, but the refraction layer with low refraction index is made of SiO₂.
